(19) United States
(12) Patent Application Publication
(10) Pub. No.: US 2004/0018741 A1
(43) Pub. Date: Jan. 29, 2004

(54) Method For Enhancing Critical Dimension Uniformity After Etch

(75) Inventors: Shashank C. Deshmukh, San Jose, CA (US); Steven J. Jones, Sunnyvale, CA (US); Meihua Shen, Fremont, CA (US); Thorsten B. Lill, Santa Clara, CA (US); John P. Holland, San Jose, CA (US); Michael Barnes, San Ramon, CA (US); Dragan V. Podlesnik, Palo Alto, CA (US)

Correspondence Address: PATENT COUNSEL, MS/2061, APPLIED MATERIALS, INC., Legal Affairs Department, P.O. Box 450A, Santa Clara, CA, 95052, US

(73) Assignee: Applied Materials, Inc.

(21) Appl. No.: 10/206,634

(22) Filed: Jul. 26, 2002

(51) Int. Cl. H01L 21/302; H01L 21/461

(52) U.S. Cl. 438/710

(57) ABSTRACT

One embodiment of the present invention is an etching method for use in fabricating an integrated circuit device on a wafer or substrate in an inductively coupled plasma reactor in a passivation-driven etch chemistry, which method includes steps of: (a) providing a passivation-driven etch chemistry precursor in a chamber of the reactor wherein a first coil is disposed to supply energy primarily to an outer portion of the chamber and a second coil is disposed to supply energy primarily to an inner portion of the chamber; and (b) providing power to the first coil and the second coil in a ratio of power supplied to the first coil and power supplied to the second coil greater than 1.

### TECHNICAL FIELD OF THE INVENTION

One or more embodiments of the present invention pertain to methods for etching used in fabricating integrated circuit (“IC”) structures.

### BACKGROUND OF THE INVENTION

As is well known, inductively coupled, RF plasma etch reactors are utilized to perform one or more etch processes used to fabricate integrated circuit (“IC”) structures. In addition, as is also well known, some such inductively coupled, RF plasma etch reactors utilize a plurality of RF coils, typically two coils, in an attempt to provide plasma uniformity in an etch processing chamber over a broad range of etch processes. U.S. Pat. No. 5,731,565 discloses inductively coupled, RF plasma etch reactors that utilize a plurality of RF coils, and U.S. Pat. No. 6,165,311 discloses other inductively coupled, RF plasma etch reactors that utilize a plurality of RF coils. Another inductively coupled, RF plasma etch reactor that utilizes a plurality of RF coils is a DPS II (“decoupled plasma source”) polysilicon etch tool (a “DPS II” tool) that is available from Applied Materials, Inc. of Santa Clara, Calif. The DPS II tool is an inductively coupled, RF plasma etch reactor that generates and sustains a plasma utilizing two solenoidal coils (an inner coil and an outer coil) overlying the ceiling of an etch processing chamber. The two solenoidal coils are powered by a source RF power supply which supplies a source power (W_{S}) at a frequency of about 13.56 MHz. In particular, the source RF power supply applies power W_{S} to the outer and inner coils through a software-driven current splitter. For the DPS II tool, among other things, a typical etch process recipe may specify W_{S} and Rₐ (i.e., a ratio of power supplied to the outer coil and to the inner coil by the source RF power supply).

One or more problems associated with the use of inductively coupled, RF plasma etch reactors that utilize a plurality of RF coils in general is described illustratively, but specifically, below with respect to the DPS II tool to enable a better understanding these problems.

In using a DPS II tool to carry out planarization and recess etch processes, typical planarization and recess etch chemistries (for example, and without limitation, SF₆, CF₄, or Cl₂ based etch chemistries) are etchant-dominated chemistries such as, for example, and without limitation, 3-gas etch chemistries (for example, and without limitation, Cl₂/CF₄/N₂ or Cl₂/SF₆/N₂ etch chemistries) or 4-gas etch chemistries (for example, and without limitation, HBr/Cl₂/CF₄/He—O₂ etch chemistries). 3-gas etch chemistries and 4-gas etch chemistries are useful because they are “self cleaning” chemistries, and as such, they can increase chamber productivity by reducing the number of chamber cleans that must be performed during processing.

For etch processes utilizing such etchant-dominated chemistries, for example in conjunction with the DPS II tool, it has been determined that Rₐ can be used as a control parameter to optimize etch rate uniformity across a wafer. For example, for such etch processes, the dependence of etch rate uniformity on Rₐ is a monotonic function. In particular, for example, in performing a planarization etch, the etch rate uniformity can be tuned from “center fast” to “edge fast” by continuously increasing Rₐ.

However, other etch chemistries, such as passivation-driven etch chemistries, may be better suited than etchant-dominated etch chemistries for some etch process applications such as, for example, and without limitation, a mask-open etch process. This is believed to be the case, at least in part, because of the following. In a plasma etch process at high power density, a large number of radicals, ions and electrons are present in the plasma, and as a result, the plasma sheath thickness is reduced. This, in turn, reduces ion energy, and enables chemical reactions to reduce critical dimensions. It is believed that passivation-driven etch chemistries produce passivation of sidewalls that helps counter this effect.

FIG. 2 shows a pictorial representation of a cross section of a typical structure used to fabricate a transistor on a wafer or substrate. As shown in FIG. 2, the structure includes: (a) gate oxide (“Gox”) layer 1010 that is formed on substrate 1000; (b) polysilicon layer 1020 that is formed over Gox 1010; (c) hardmask (“HM”) layer 1030 that is formed over polysilicon layer 1020 (for example, and without limitation, HM layer 1030 may be a silicon nitride layer); (d) BARC layer 1040 (as is well known, BARC or “bottom antireflective coating” is an organic antireflective coating that is typically produced by a spin-on process) that is formed over HM layer 1030; and (e) patterned photoresist (“PR”) layer 1050 that is formed over BARC layer 1040.

A mask-open etch process entails etching hardmask layer 1030 (typically, a 1500 to 2000 Å thick nitride layer) through photoresist layer 1050 and BARC layer 1040. In such a mask-open etch process application, it is believed that a passivation-driven etch chemistry may provide better nitride hardmask to photoresist selectivity than etchant-driven chemistries. For example, and without limitation, it is believed that a nitride hardmask etch process using a CH₂F₂/CF₄/He chemistry that is highly polymerizing can provide good etch rate selectivity. In particular, this is believed to be the case at least in part because of the following. In such an etch process, CH₂F₂ dissociation produces CFₓ monomer precursors that polymerize to produce polymers, and it is believed that these polymers: (a) increase nitride hardmask to photoresist selectivity; (b) provide sidewall passivation which produces tapered nitride hardmask profiles that maintain critical dimensions (“CD”) (i.e., sidewall passivation prevents side etching of hardmask walls—which side etching reduces CD); and (c) provide passivation that is greater for isolated features than dense features to help prevent profile and CD-bias microloading. Microloading refers to etching differences that occur between features that are isolated and features that are densely packed. Further, CD-bias refers to a difference between a critical dimension after and prior to etching.

However, for an inductively coupled, RF plasma etch reactor utilizing a plurality of RF coils such as the DPS II tool, for passivation-driven etch chemistries, it has been determined that Rₐ does not serve as a control parameter for hardmask etch rate uniformity across a wafer in accordance with lessons learned from providing etch rate uniformity in etchant-dominated etch processes. For example, it has been discovered that for a passivation-driven chemistry such as CH₂F₂/CF₄/He, the etch uniformity is always edge fast. In addition, CD-bias data (especially for isolated features) shows a large CD gain, i.e., positive CD-bias) at the wafer center when compared with CD-bias at the wafer edge. In particular, the CD gain falls rapidly at the wafer edge. Specifically, this means that sidewall profiles are more tapered at the wafer edge than at the wafer center.

In light of the above, there is a need for one or more methods to solve one or more of the above-identified problems.

### SUMMARY OF THE INVENTION

One or more embodiments of the present invention advantageously satisfy one or more of the above-identified problems in the art. Specifically, one embodiment of the present invention is an etching method for use in fabricating an integrated circuit device on a wafer or substrate in an inductively coupled plasma reactor in a passivation-driven etch chemistry, which method comprises steps of: (a) providing a passivation-driven etch chemistry precursor in a chamber of the reactor wherein a first coil is disposed to supply energy primarily to an outer portion of the chamber and a second coil is disposed to supply energy primarily to an inner portion of the chamber; and (b) providing power to the first coil and the second coil in a ratio of power supplied to the first coil and power supplied to the second coil greater than 1.

### BRIEF DESCRIPTION OF THE FIGURE

FIG. 1 shows a pictorial representation of salient features of a DPS II (“decoupled plasma source”) polysilicon etch tool available from Applied Materials, Inc. of Santa Clara, Calif.;

FIG. 2 shows a pictorial representation of a cross section of a typical film structure used to fabricate a transistor on a wafer or substrate;

FIGS. 3 and 4 show across-the-wafer nitride CD-bias range for two values of Rₐ; and

FIG. 5 shows CD uniformity dependence on process variables for a nitride hardmask etch process.

### Detailed Description

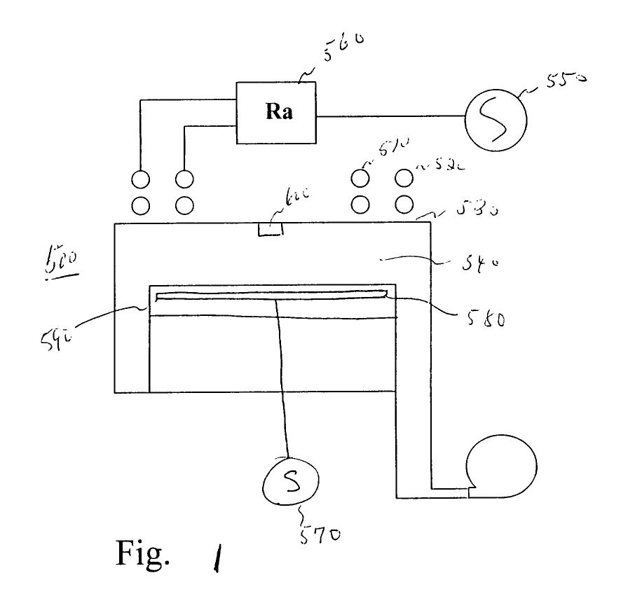

One or more embodiments of the present invention provide a method to control CD-bias uniformity across a wafer in a passivation-driven etch process, for example, and without limitation, a mask open etch process carried out in an inductively coupled, RF plasma etch processing tool such as, for example, and without limitation, a DPS II polysilicon etch tool that is available from Applied Materials, Inc. of Santa Clara, Calif. (a “DPS II” tool). FIG. 1, shows a pictorial representation of salient features of DPS II tool 500. As shown in FIG. 1, DPS II tool 500 is an inductively coupled, RF plasma etch reactor that generates and sustains a plasma utilizing two solenoidal induction coils (inner coil 510 and outer coil 520) overlying ceiling 530 of etch processing chamber 540. Coils 510 and 520 are powered by source RF power supply 550 that supplies source power W_{S} (in watts) at a frequency of about 13.56 MHz through software-driven, current splitter 560. Current splitter 560 includes a series/shunt reactance combination (not shown) that controls RF current flowing in both coils. Second RF supply 570 supplies bias power W_{b} (in watts) at a frequency of about 13.56 MHz to cathode 580 disposed in wafer pedestal 590. As a result, DPS II tool 500 includes a decoupled plasma source that separates or decouples control of ion generation (source) from control of ion acceleration energy (bias), enabling each to vary substantially independently from the other. Wafer pedestal 590 also includes an electrostatic chuck (not shown) that holds a wafer or substrate securely, and wafer pedestal 590 flows a gas, for example, He, across a backside of the wafer (a “backside cooling gas”) to conduct heat between the wafer and wafer pedestal 590. In this manner wafer pedestal 590 acts as a heat sink. In particular, in at least one version of DPS II tool 500, the backside cooling gas flows in two zones having different backside cooling gas pressures to better control temperature across the wafer. The dual zone, electrostatic chuck provides good control of temperature across the wafer for enhanced temperature uniformity to the wafer edge. Lastly, the DPS II tool includes center gas feed 600. In light of the above, among other things, a typical etch process recipe will specify, among other things, W_{S} and Rₐ (i.e., a ratio of power supplied to outer coil 520 and to inner coil 520 by source RF power supply 550).

A typical mask-open etch process entails etching a hardmask layer (typically, a silicon nitride layer or a silicon oxide layer) through a photoresist layer and a BARC layer (as is known, BARC or “Bottom Antireflective Coating” is an organic antireflective coating that is typically produced by a spin-on process). It has been discovered that certain issues drive etch and CD-bias uniformity in the DPS II tool: (a) the electromagnetic power density transmitted into the DPS II tool at various positions due to various values of Rₐ; (b) the temperature of an edge of the wafer as compared to a center of the wafer due to two zone backside cooling; and (c) the distribution of gas due to the DPS II center gas feed. For example, if the edge of the wafer is hotter than the center, in certain passivation-driven etch processes, the reactivity of the chemical species at the edge will be higher, and thereby, result in CD loss (i.e., negative CD-bias). Also, due to center gas feed 600, the resulting supply of etchants at the center of ceiling 530 of etch processing chamber 540 causes preferential dissociation of an etchant such as CH₂F₂ to take place at the center of etch processing chamber 540. This leads to an increased supply of CFₓ monomer precursors that can polymerize to provide more passivation at the wafer center when compared to passivation at the wafer edge. This, in turn, causes: (a) the etch rate at the wafer center to be lower than the etch rate at the wafer edge, and (b) CD gain at the wafer center to be larger than CD gain at the wafer edge. From etch uniformity dependence on Rₐ data, it was determined that optimum nitride etch uniformity is achieved at lowest Rₐ, i.e., when most of the source power was delivered to inner coil 510. However, increased power deposition to the center of etch processing chamber 540 leads to excess CD gain at the wafer center.

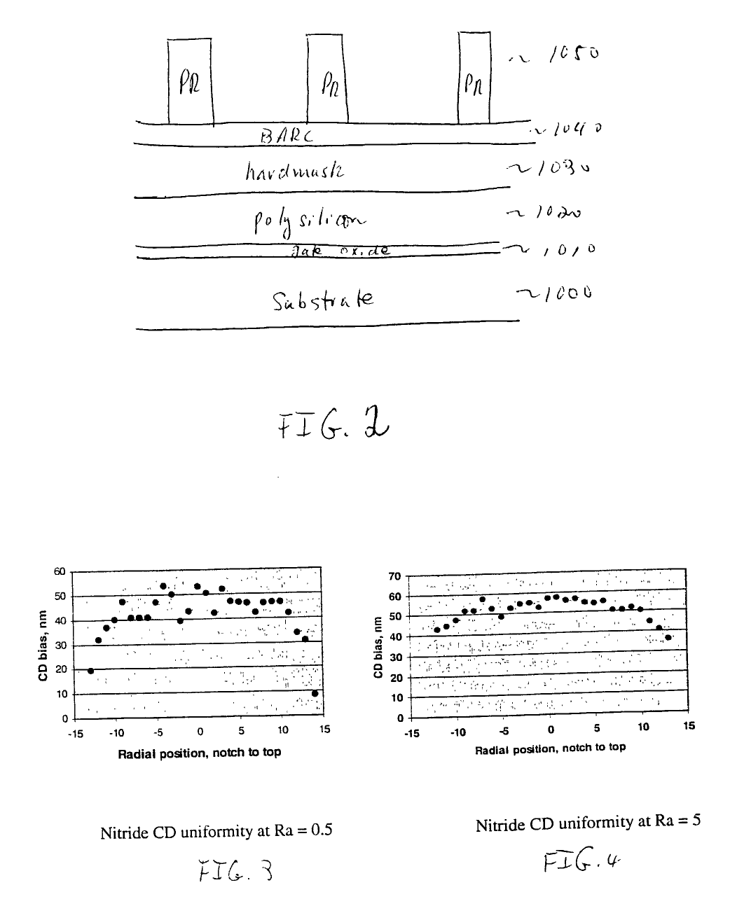

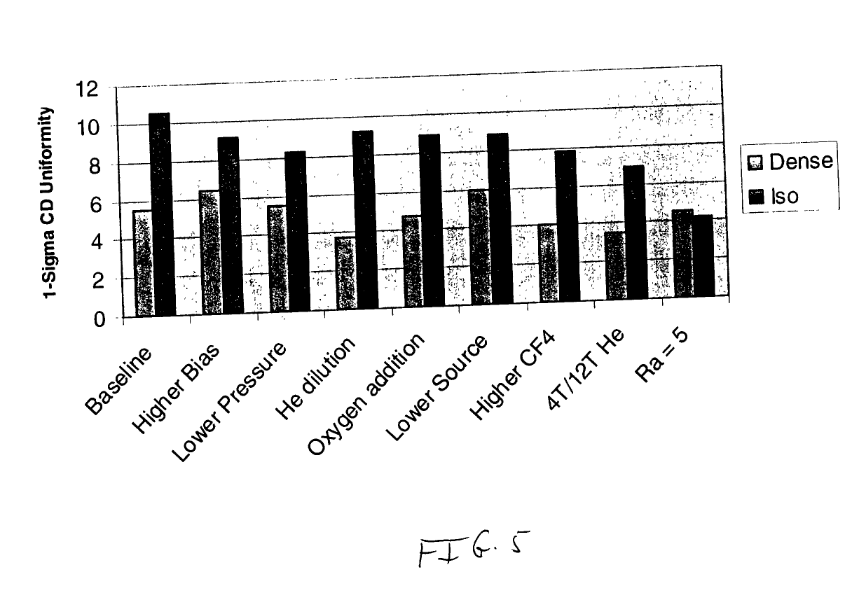

In accordance with one or more embodiments of the present invention, these issues are resolved by delivering more of source power W_{S} to the wafer edge (for example, higher current is applied to outer coil 520) by setting Rₐ>1. As a result, for one or more embodiments of the present invention that provide a passivation-driven etch process utilizing an etchant comprising CH₂F₂, it is believed that setting Rₐ>1 leads to fewer monomer precursors being available at the wafer center, and more at the wafer edge. It is believed that the reason for this is that more power is required to crack the CH₂F₂. As a result, this preferential CH₂F₂ dissociation at the wafer edge increases CD gain there, and provides a more uniform CD distribution across the wafer. In one particular example, as shown in FIGS. 3-4, across-the-wafer nitride CD-bias range was improved from 45 nm at Rₐ=0.5 (a parameter that corresponds to a best nitride etch rate uniformity condition) to 21 nm at Rₐ=5 for isolated features. As one can see this, it was discovered that CD uniformity does not follow etch rate uniformity, and that CD uniformity is enhanced using a process recipe that would seem to reduce etch rate uniformity. Thus, although using a high value of Rₐ=5 produces a nitride etch uniformity that is not optimal, nevertheless, the CD-bias uniformity across the wafer has a smaller CD-bias range. In addition, the wafer edge nitride etch profiles became more tapered, with better center-to-edge uniformity.

FIG. 5 shows CD uniformity dependence on process variables for a nitride hardmask etch process starting from the following baseline nitride etch process chemistry for a 200 mm DPS II tool: a flow rate of 70 sccm for CF₄; a flow rate of 30 sccm for CH₂F₂; a flow rate of 200 sccm for He; a chamber pressure of 7 mT; power supplied to the outer and inner solenoidal coils of 400 Wₛ with the ratio of power supplied to the outer and inner coils Rₐ=0.5; power supplied to the pedestal of 250 W_{b}; and the temperature of the wafer pedestal is maintained in a range from about 30° C. to about 50° C. As shown in FIG. 5: (a) for dense features, CD uniformity improvement came from: (i) additional He dilution (this provides lower residence time for the etchants), (ii) higher CF₄/CH₂F₂ ratio (this reduces the passivation-driven nonuniformity), (iii) 4 T/12 T inner to outer pressures for He backside cooling gas (this makes the center of the wafer hotter), and (iv) higher Rₐ; and (b) for isolated features, CD uniformity improvement came from: (i) 4 T/12 T inner to outer pressures for He backside cooling gas, and (ii) higher Rₐ.

In an alternative embodiment, to promote CD-bias uniformity, instead of, or together with, utilizing a higher Rₐ, one may utilize an edge gas feed mechanism such as injection tubes disposed about a periphery of the chamber substantially at the level at which the wafer is disposed during processing, or one may preferentially inject polymerizing gas at the edge of the wafer using such an edge gas feed mechanism.

Although the description above related to the DPS tool, embodiments of the present invention are not limited thereto. In general, one or more embodiments of the present invention relate to inductively coupled, RF plasma etch reactors utilizing a plurality of RF coils. For example, one or more such embodiments of the present invention relate to inductively coupled, RF plasma etch reactors utilizing a plurality of RF coils such as, for example, and without limitation, those of the types disclosed in U.S. Pat. No. 5,731,565 and U.S. Pat. No. 6,165,311. In addition, one or more embodiments of the present invention relate to inductively coupled, RF plasma etch reactors utilizing a plurality of RF coils wherein a first RF coil supplies energy primarily to an outer portion of an etch chamber and a second RF coil supplies energy primarily to an inner portion of the etch chamber to generate a plasma therein. As such, in one such embodiment, a coil that supplies energy to the outer portion may be disposed about the chamber rather than being disposed over a ceiling of the chamber. Further, in accordance with one or more further embodiments of the present invention, all or a portion of the first or the second RF coils may have a shape that is substantially two dimensional, which two dimensional shape conforms substantially to a shape of a surface of a portion of the ceiling over which it is disposed.

Those skilled in the art will recognize that the foregoing description has been presented for the sake of illustration and description only. As such, it is not intended to be exhaustive or to limit the invention to the precise form disclosed. For example, the term wafer also refers to substrates of all types including, without limitation, semiconductors, and glass. In addition, although embodiments of the present invention were discussed for a hardmask that comprises a nitride layer, the such embodiments also relate to hardmasks such as, for example, and without limitation, an oxide layer. In further addition, embodiments of the present invention relate also to chemistries that require high photoresist selectivities, and rely on a polymerizing agent such as, for example, and without limitation, CH₂F₂, C₄F₈, CHF₃, C₄F₆, and so forth.

What is claimed is:

1. An etching method for use in fabricating an integrated circuit device on a wafer or substrate in an inductively coupled plasma reactor in a passivation-driven etch chemistry, which method comprises steps of:
providing a passivation-driven etch chemistry precursor in a chamber of the reactor wherein a first coil is disposed to supply energy primarily to an outer portion of the chamber and a second coil is disposed to supply energy primarily to an inner portion of the chamber to generate a plasma therein; and
providing power to the first coil and the second coil in a ratio of power supplied to the first coil and power supplied to the second coil greater than 1.

2. The method of claim 1 wherein the first coil is an outer solenoidal coil and the second coil in an inner solenoidal coil that is disposed over a ceiling of the chamber.

3. The method of claim 2 wherein the first coil is disposed over the ceiling.

4. The method of claim 1 wherein the first coil is an outer coil that is disposed at least partially over a ceiling of the chamber and the second coil is an inner coil that is disposed over the ceiling of the chamber.

5. The method of claim 4 wherein the second coil has a shape that is substantially two dimensional, which shape conforms substantially to a shape of a surface of a portion of the ceiling over which it is disposed.

6. The method of claim 3 wherein the precursor includes one or more of CH₂F₂, C₄F₈, CHF₃, and C₄F₆.

7. The method of claim 1 wherein the step of providing the passivation-driven etch chemistry precursor includes utilizing a wafer edge gas feed mechanism.

8. The method of claim 1 wherein the step of providing the passivation-driven etch chemistry precursor includes injecting polymerizing gas at an edge of the wafer.

9. The method of claim 3 wherein the method is a mask open etch process that comprises steps of:
providing a passivation-driven etch chemistry precursor in the chamber that includes one or more of CH₂F₂, C₄F₈, CHF₃, and C₄F₆; and
providing power to the outer coil and the inner coil in a ratio of power supplied to the outer coil and power supplied to the inner coil greater than 1.
